(19) United States
(12) Patent Application Publication
(10) Pub. No.: US 2003/0066016 A1
(43) Pub. Date: Apr. 3, 2003

(54) Methodology for detecting lost packets

(76) Inventor: Eric Wehage, Tenino, WA (US)

Correspondence Address: Stephen T. Neal, Blakely, Sokoloff, Taylor & Zafman LLP, Seventh Floor, 12400 Wilshire Boulevard, Los Angeles, CA, 90025-1030, US

(21) Appl. No.: 09/968,275

(22) Filed: Sep. 28, 2001

(51) Int. Cl. H03M 13/00

(52) U.S. Cl. 714/781

(57) ABSTRACT

A system and method are described for detecting packet loss using an error checking signature, such as a cyclical redundancy check (CRC), while transmitting packets between a sender and a receiver. A counter is present on both the sender and the receiver, the two counters initially synchronized with each other. The CRC is generated using a sequence number provided by the counter at the sender. As the packets are sent, the sender counter is incremented. The receiver uses a sequence number from the receiver counter to decode the CRC. If all the packets are received, the sequence number to decode should match the sequence number to encode. Therefore, if the CRC does not decode properly, a packet has been lost or corrupted. A message to resend the packets is sent to the sender. The receiver counter is not incremented until the proper packet is received and decoded.

### FIELD OF THE INVENTION

The field of the invention relates to packet transmission. More specifically, it relates to the combination of an error checking method and link level retry to detect lost packets.

### BACKGROUND OF THE INVENTION

A common error checking method that requires a check signature is cyclical redundancy check (CRC). CRC determines if a packet has been corrupted during transmission between sender and receiver. CRC does not determine if packets have been lost. FIG. 1 illustrates an N-bit divisor (D) used with the message (M) to create a CRC remainder (R) (processing block 100). Shifting the message N bits left creates a shifted message (SM) (processing block 110). For example, if a divisor equals 1011 and a message equals 101100101, then the shifted message equals 1011001010000. The remainder of the shifted message divided by the divisor is created (processing block 120). Using the previous example, by dividing the shifted message 1011001010000 by 1011, a remainder of 0011 is produced. The message and the remainder are incorporated into a data packet (processing block 130). A sender then sends the data packet to a receiver (processing block 140). The receiver then divides the sum of the shifted message plus the remainder by the divisor (processing block 150). If the sum of the shifted message plus the remainder divided by the divisor produces a remainder of zero (processing block 160), then the data packet is not corrupted (processing block 170). If not, then the data packet is corrupted (processing block 180).

A cyclical redundancy check can be used in concert with a link level retry. A link level retry stores a copy of each packet in a first-in-first-out (FIFO) buffer as the packet is sent. The receiver then sends a message back to the sender once the CRC has been decoded. If the decoding was successful, the packet is erased. If the decoding is not successful, the packet is resent. This only works for packets that are corrupted, not packets that are lost. What is needed is a method for determining not only when a packet is corrupted, but also when a data packet is lost. Additionally, this needs to be done without consuming too much bandwidth.

### BRIEF DESCRIPTION OF THE DRAWINGS

The present invention is illustrated by way of example and not limitation in the figures of the accompanying drawings in which like references indicated similar elements and in which:

FIG. 1 is a flow chart of one embodiment of a process for encoding and decoding a cyclical redundancy check.

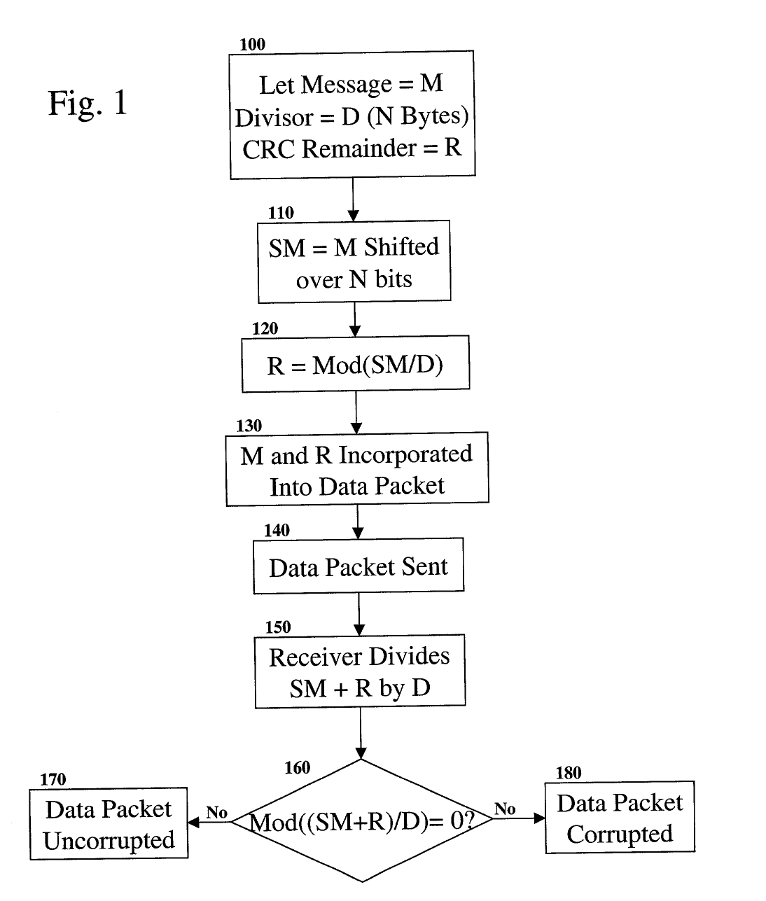

FIG. 2 is a simplified block diagram of one embodiment of a system for performing a cyclical redundancy check.

FIG. 3 is a block diagram of one embodiment of a system for performing a sequence number based cyclical redundancy check.

FIG. 4 is a flowchart of one embodiment of a process for encoding and transmitting a data packet.

FIG. 5 is a flowchart of one embodiment of a process for decoding and receiving a data packet.

FIG. 6 is a flowchart of one embodiment of a process for resending missing data packets.

FIG. 7 is a block diagram of one embodiment of a hub-interface used to interconnect two separate components within a chipset.

### DETAILED DESCRIPTION

A system and method are described for detecting packet loss using an error-checking signature, such as a cyclical redundancy check (CRC), while transmitting packets between a sender and a receiver. The sender and receiver have a counter. Both counters are initially synchronized with each other. The CRC code is generated using a sequence number provided by the counter at the sender. As the packets are sent, the counter of the sender is incremented. The receiver uses a sequence number from the receiver counter to decode the CRC code. If all the packets are received, the sequence number to decode should match the sequence number to encode. Therefore, if the CRC code does not decode properly, a packet has been lost or corrupted. If a packet has been lost or is corrupted, then a message to resend the packets is sent to the sender. The receiver counter is not incremented until the proper packet is received and decoded.

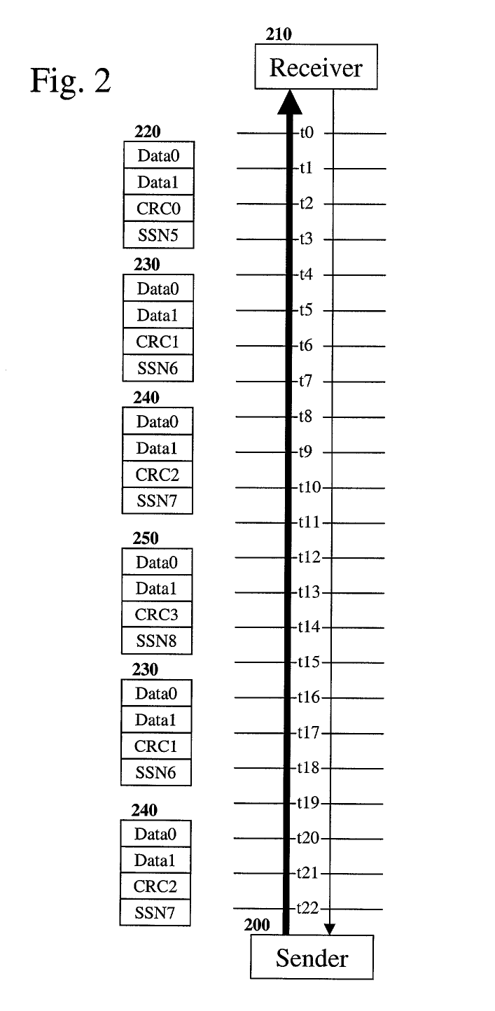

A simplified version of the system is shown in FIG. 2. Referring to FIG. 2, a sender 200 transmits packets of information to a receiver 210. A first packet 220 includes a first sender sequence number to create a first CRC code to be attached to one or more data segments of the packet. For example, CRC0 is produced from sequence number 5. In one embodiment, the sender sequence number does not have to start from zero, as long as the sender sequence number equals the receiver sequence number. In an alternate embodiment, the data packet does not include a sequence number. A second packet 230 is then transmitted, and is subsequently lost. When the CRC of the third packet 240 is decoded, the sender sequence number 7 used to encode the CRC of the third data packet 240 will not match the receiver sequence number 6. Therefore, the CRC will not decode properly, and the third data packet is deemed corrupted. A message is sent to the sender indicating that the packet decoded improperly. The fourth packet 250 is also decoded, but will fail for the same reason as the third packet 240. Once the second packet 230 is properly sent, the receiver sequence number is then incremented.

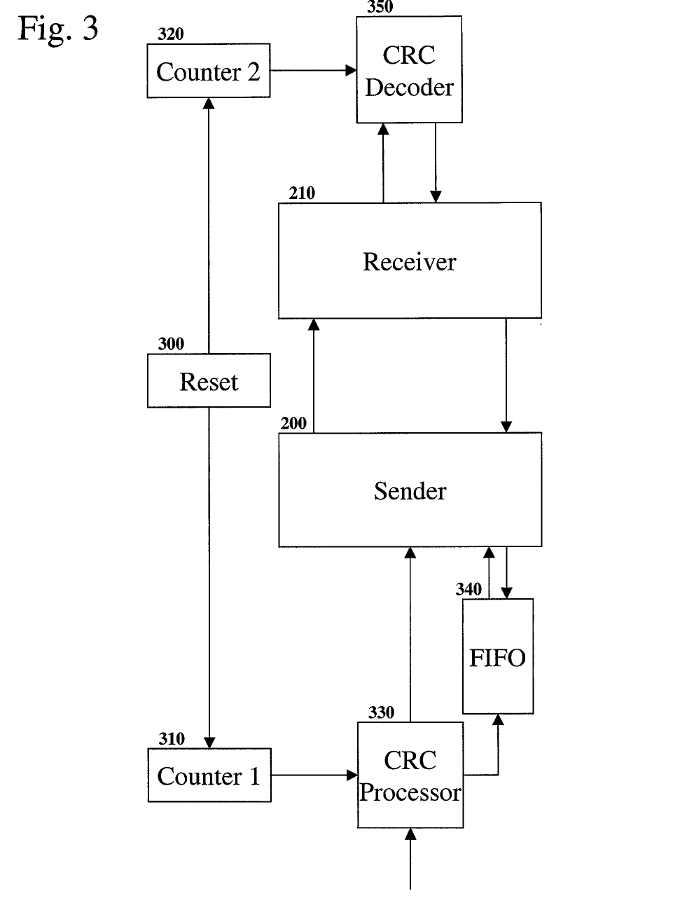

A support system for sender 200 and receiver 210 is illustrated in FIG. 3. A reset signal 300 allows both sender counter (counter1) 310 and receiver counter (counter2) 320 to be synchronized. Alternatively, the counters are pre-programmed to reset to zero when the last frame is sent or received. CRC processor 330 is coupled to sender 200 and generates a CRC code for each data packet using a sender sequence number from sender counter 310. A copy of the packet is then placed into buffer 340. The copy of the data packet is sent to receiver 210 if the packet is lost or corrupted. Receiver 210 sends the sequence number of the missing or corrupt data packet to sender 200. In one embodiment, buffer 340 is a FIFO buffer. For a FIFO buffer, no sequence number needs to be sent, as the data packets are read from the buffer in the order that they are sent. Once receiver 210 receives a data packet, CRC decode 350 (e.g., a processor) decodes the CRC code of the data packet.

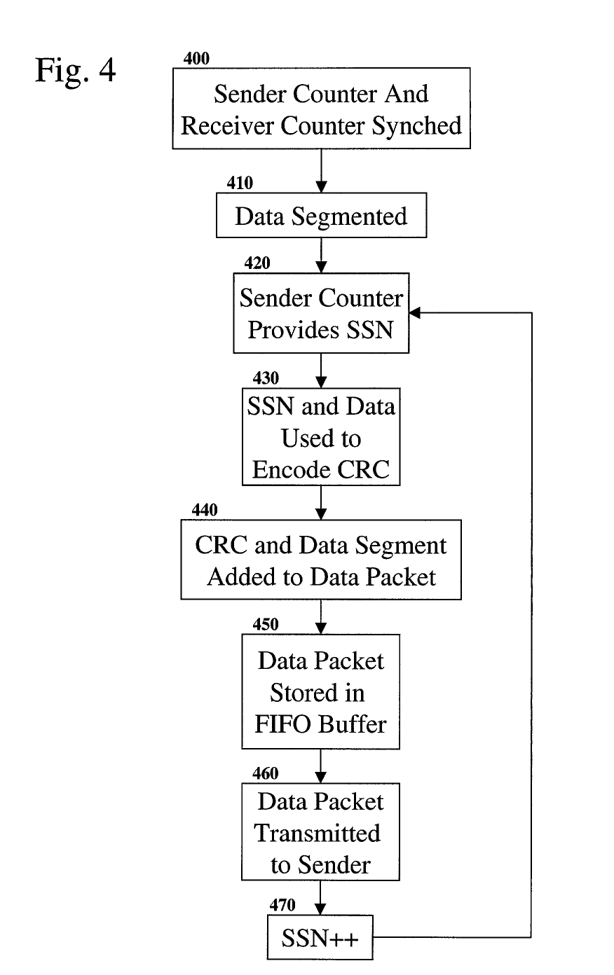

One embodiment of a process for coding and sending data packets is illustrated in FIG. 4. A sender counter and a receiver counter are synchronized (processing block 400) in a manner well known in the arts. The data to be transmitted is separated into segments for transmittal (processing block 410). The sender counter provides a sender sequence number (SSN) (processing block 420). The sender sequence number and a data segment are used to generate a CRC code (processing block 430). The CRC code and data segment are added to a header and other information to form a data packet (processing block 440). In one embodiment, the sender sequence number is also added to the data packet. A copy of the data packet is stored in a FIFO buffer (processing block 450). The data packet is transmitted to the sender (processing block 460). The counter increments the sender sequence number (processing block 470). The counter provides the new sender sequence number for generating a new CRC code for a new data packet (processing block 420).

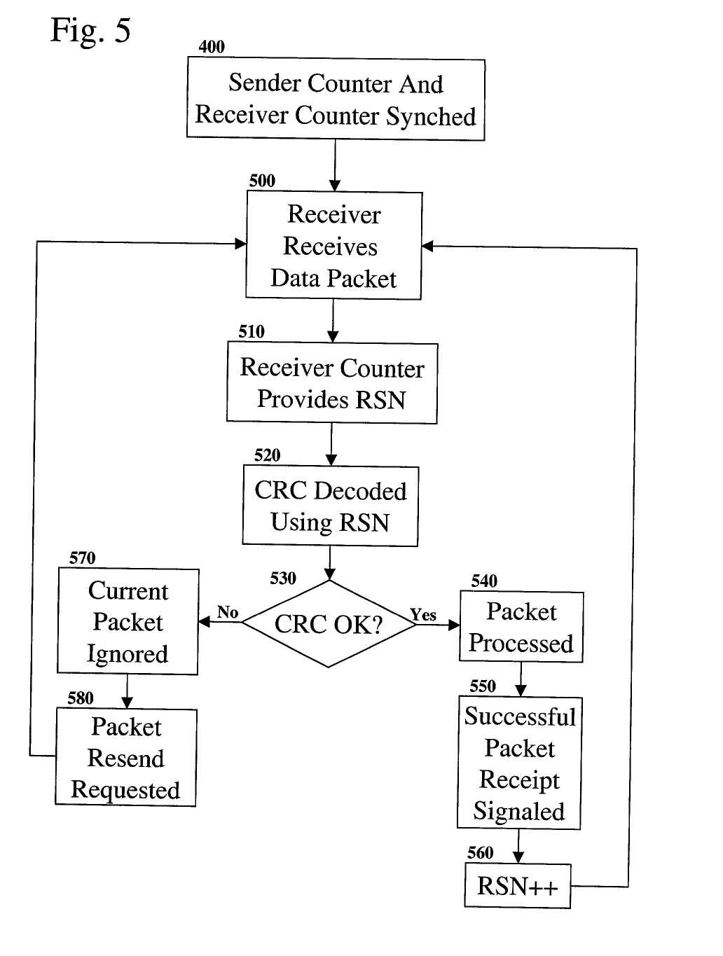

One embodiment of a process for decoding and receiving data packets is illustrated in FIG. 5. The sender counter and the receiver counter are synchronized (processing block 400). The receiver receives a data packet (processing block 500). The receiver counter provides a receiver sequence number (processing block 510). The CRC code of the data packet is decoded using the receiver sequence number (processing block 520). In an alternate embodiment, the receiver sequence number is compared with the sender sequence number contained within the packet. If the CRC code decodes properly (processing block 530), the packet is processed (processing block 540). The receiver signals the sender that the packet was received successfully (processing block 550). The counter increments the receiver sequence number (processing block 560), then the next data packet is received (processing block 500). If the CRC code does not decode properly (processing block 530), the current packet is ignored (processing block 570), and the receiver signals the sender to resend the packet (processing block 580). In one embodiment, the resend indication includes the sequence number of the missing packet. The next data packet is received (processing block 500).

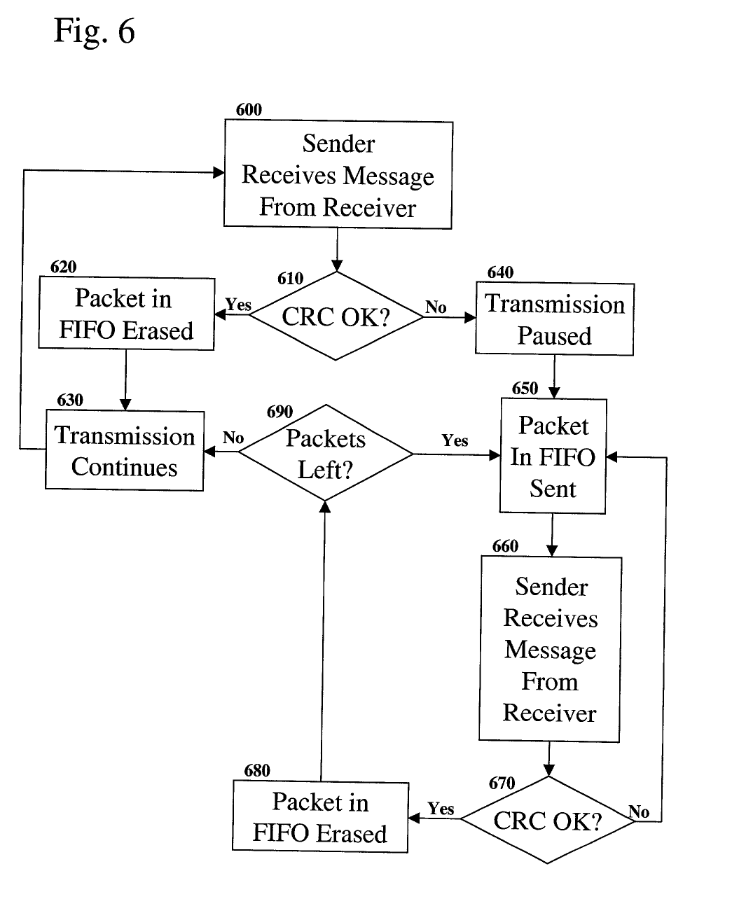

One embodiment of a process for resending the data packets is illustrated in FIG. 6. The sender receives a message from the receiver (processing block 600). If the message from the receiver indicates that the CRC decoded properly (processing block 610), the corresponding copy of the data packet in the FIFO buffer is erased (processing block 620). The transmission continues (processing block 630), the sender receiving the next message from the receiver (processing block 600). If the message from the receiver indicates that the CRC decoded improperly (processing block 610), the sender pauses transmission of further data packets (processing block 640). The next available packet in the FIFO buffer is sent (processing block 650). The sender receives a message from the receiver indicating whether the resent data packet decoded properly (processing block 660). If the resent packet did not decode properly (processing block 670), that packet is sent again (processing block 650). If the resent packet decoded properly (processing block 670), the resent packet in the FIFO buffer is erased (processing block 680). If more packets are in the FIFO buffer (processing block 690), the next available data packet in the FIFO buffer is sent to the receiver (processing block 650). If no more packets are in the FIFO buffer (processing block 690), transmission continues (processing block 630), and the sender receives the next message from the receiver (processing block 600).

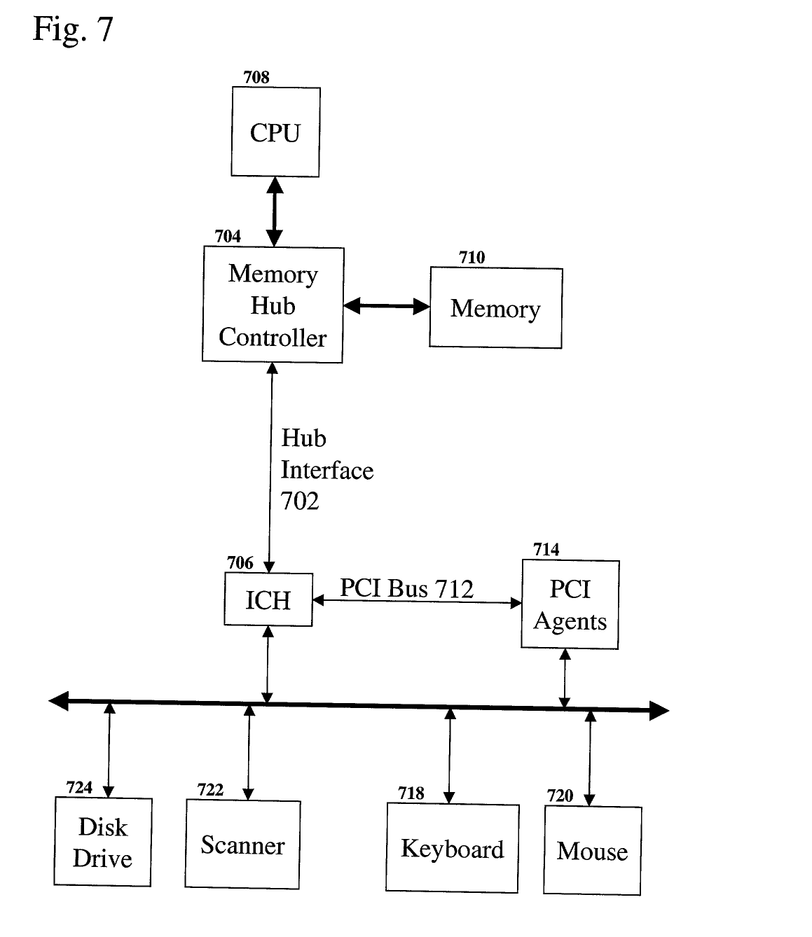

One embodiment of a system in which CRC lost packet detection is used is illustrated in FIG. 7. More specifically, FIG. 7 illustrates one embodiment of the hub-interface 704 used to interconnect two separate components (i.e., hub agents) within a chipset. The hub agents provide a central connection between two or more separate buses and/or other types of communication lines.

For example, as further shown in FIG. 7, the chipset includes a memory control hub 704 (MCH) and an input/output (ICH) hub 706. The memory control hub 704, as shown in FIG. 7, provides an interconnection/hub between one or more Central Processing Units 708 (CPU) and the system memory 710.

The ICH 706 provides an interconnection between various peripheral components within the system (e.g. a keyboard 718, disk drive 724, scanner 722 and/or mouse 720.) Moreover, the external busses and their agents (e.g., Peripheral Component Interconnect (PCI) bus 712 and PCI agents 714), interconnect indirectly with the memory 710 and CPU 708 via the hub-interface 702, by interconnecting with the ICH 706, rather than interconnecting directly with the memory control hub 704.

By using the hub-interface to interconnect the memory control hub 704 and the ICH 706, improved access is provided between I/O components and the CPU/memory subsystem (e.g., increased bandwidth, protocol independence, and lower latency.) In addition, the hub-interface may also improve the scalability of a computer system (e.g., upgrading from a base desktop platform to high-end desktop platforms or workstation platform) by providing a backbone for I/O building blocks.

In an alternative embodiment, the CPU and the MCH are integrated on a single semiconductor unit 730, wherein the single semiconductor unit 730 is coupled to the ICH via the hub-interface. In another alternative embodiment, the MCH and a graphics unit 732 (e.g. control/accelerator) are integrated on a single semiconductor unit 730, wherein the single semiconductor unit 730 is coupled to the ICH via the hub-interface. In yet another alternative embodiment, the MCH, the graphics unit 732 and the CPU are integrated on a single semiconductor unit 730, wherein the single semiconductor unit 730 is coupled to the ICH via the hub-interface.

The transaction, protocol and physical layers for one such system is described in “Method and Apparatus for an Improved Interface Between Computer Components”, U.S. patent application Ser. No. 09/428,134, filed on Oct. 26, 1999, assigned to the corporate assignee of the present invention.

The technique described above may be implemented as a set of instructions to be executed and stored in the memory of a computer system (e.g., set top box, video recorders, etc.). The instructions to perform the method described above could alternatively be stored on other forms of machine-readable media, including magnetic and optical disks. For example, the method of the present invention could be stored on machine-readable media, such as magnetic disks or optical disks, which are accessible via a disk drive (or computer-readable medium drive). Further, the instructions can be downloaded into a computing device over a data network in a form of compiled and linked version.

Alternatively, the logic to perform the methods as discussed above, could be implemented by additional computer and/or machine readable media, such as discrete hardware components as large-scale integrated circuits (LSI's), application-specific integrated circuits (ASIC's), firmware such as electrically erasable programmable read-only memory (EEPROM's); and electrical, optical, acoustical and other forms of propagated signals (e.g., carrier waves, infrared signals, digital signals, etc.); etc.

Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. A system, comprising:
a transmitter to send data packets that include an error checking signature;
a first counter coupled to the transmitter and including a count that is incremented with each data packet sent to produce a first sequence number for use in generating the error checking signature;

2. The system of claim 1, further comprising:
a receiver to receive the data packets; and
a second counter coupled to the receiver, the second counter incrementing with each data packet received to produce a second sequence number to decode the cyclical redundancy check.

3. The system of claim 2, wherein the receiver sends a first indication to the transmitter indicating a data packet failure if the receiver fails to decode the error checking signature using the second sequence number.

4. The system of claim 3, wherein the first message includes the second sequence number.

5. The system of claim 4, wherein the transmitter resends the data packet corresponding to the second sequence number.

6. The system of claim 3, further including a buffer to store a copy of each data packet that is sent.

7. The system of claim 6, wherein, if the cyclical redundancy check is successfully decoded, the receiver sends a second message to the transmitter.

8. The system of claim 7, wherein the buffer is a first-in, first-out (FIFO) buffer.

9. The system of claim 8, wherein the copy of a data packet is erased once the corresponding second message is received.

10. The system of claim 9, wherein the next data packet in the FIFO buffer is retransmitted upon receipt of the first message.

11. The system of claim 2, wherein the first counter and the second counter can be reset to the same number simultaneously.

12. The system of claim 2, wherein the first sequence number is included in the data packet sent.

13. A method, comprising:
synchronizing a packets-received counter coupled to a receiver with a packets-sent counter coupled to a transmitter;
receiving a data packet from the transmitter, the packet containing an error checking signature;
reading a receiver sequential number from the packets-received counter; and
decoding the error checking signature using the receiver sequential number.

14. The method of claim 13, further including sending a confirmation signal back to the transmitter.

15. The method of claim 14, wherein the confirmation signal acknowledges receipt of the data packet if the error-checking signature is correct.

16. The method of claim 14, wherein the confirmation signal indicates a failure to receive the data packet if the error-checking signature is not correct.

17. The method of claim 13, further including incrementing the packets-received counter after each error-checking signature has been recorded.

18. The method of claim 13, further including:
reading a transmitter sequential number from the packets-sent counter;
encoding the error-checking signature using the transmitter sequential number; and
transmitting the data packet to the receiver, the packet containing the error-checking signature.

19. The method of claim 13, wherein the data packet includes the transmitter sequence number.

20. The method of claim 13, further including storing the data packet in a buffer coupled to the transmitter.

21. The method of claim 20, further including erasing the data packet from the buffer after a confirmation signal from the receiver confirms that the error-checking signature of the packet has been decoded.

22. The method of claim 13, further including incrementing the packets-sent counter after each error-checking signature has been sent.

23. A machine-readable storage medium tangibly embodying a sequence of instructions executable by the machine to perform a method comprising:
synchronizing a packets-received counter coupled to a receiver with a packets-sent counter coupled to a transmitter;
receiving a data packet from the transmitter, the packet containing an error-checking signature;
reading a receiver sequential number from the packets-received counter; and
decoding the error-checking signature using the sequential number.

24. The machine-readable storage medium of claim 23, further including sending a confirmation signal back to the transmitter.

25. The machine-readable storage medium of claim 23, further including incrementing the packets-received counter after each error-checking signature has been recorded.

26. The machine-readable storage medium of claim 23, further including:
reading a transmitter sequential number from the packets-sent counter;
encoding the error-checking signature using the sequential number; and
transmitting the data packet to the receiver, the packet containing the error-checking signature.

27. The machine-readable storage medium of claim 23, further including storing the data packet in a buffer coupled to the transmitter.

28. The machine-readable storage medium of claim 27, further including erasing the data packet from the buffer after a confirmation signal from the receiver confirms that the error-checking signature of the packet has been decoded.

29. The machine-readable storage medium of claim 27, further including incrementing the packets-sent counter after each error-checking signature has been sent.
